(19) United States
(12) Patent Application Publication
(10) Pub. No.: US 2025/0217765 A1
(43) Pub. Date: Jul. 3, 2025

(54) METHOD FOR DYNAMICALLY ARRANGING BATTERY STORAGE LOCATION

(71) Applicants: Cheng-Tung CHOU, Taoyuan City (TW); Jih-Hsing LEE, Taoyuan City (TW); Chih-Hsien WANG, Taoyuan City (TW)

(72) Inventors: Cheng-Tung CHOU, Taoyuan City (TW); Jih-Hsing LEE, Taoyuan City (TW); Chih-Hsien WANG, Taoyuan City (TW)

(21) Appl. No.: 19/000,783

(22) Filed: Dec. 24, 2024

(30) Foreign Application Priority Data
Dec. 28, 2023 (TW) 112151181

(51) Int. Cl. G06Q 10/087; G01R 31/367

(52) U.S. Cl. CPC G06Q 10/087; G01R 31/367

(57) ABSTRACT

The present invention provides a method for dynamically arranging battery storage locations, comprising: calculating, based on the test recipes of all batteries in the first battery group and the test recipes of all batteries in the second battery group, a first charge-discharge value of the first battery group and a second charge-discharge value of the second battery group within a target time interval; calculating, based on an additional test recipe of an additional battery within the target time interval, an additional charge-discharge value; determining whether the first charge-discharge value and the second charge-discharge value have the same sign as the additional charge-discharge value, respectively, to obtain a comparison result; and determining, based on the comparison result, whether the additional battery is to be arranged in a storage location of the first battery group or the second battery group.

### CROSS REFERENCE TO RELATED APPLICATION

The present application claims priority to Taiwan patent application Serial No. 112151181 filed on Dec. 28, 2023 the entire content of which is incorporated by reference to this application.

### BACKGROUND OF THE INVENTION

### 1. Field of the Invention

The present invention relates to a method for dynamically arranging battery storage location, particularly to a method for selecting a storage location based on charge-discharge recipes of batteries.

### 2. Description of the Prior Art

When batteries are initially manufactured, they need to undergo a formation process using a formation apparatus, which typically takes several hours, to ensure their quality. Generally, batteries are placed in storage locations within the formation apparatus, and the apparatus repeatedly charges and discharges the batteries according to their respective charge-discharge recipes. In practice, the time at which each battery enters or leaves the formation apparatus may vary. For instance, some batteries may be identified as defective during the formation process and removed from the storage locations earlier than scheduled. To maximize the capacity utilization of the formation apparatus, operators typically arrange new or to-be-formed batteries into the vacated storage locations. However, determining how to select one storage location from several available options for a new or to-be-formed battery, in a way that enhances the energy efficiency of the formation apparatus, remains a challenge that needs to be addressed.

### SUMMARY OF THE INVENTION

The present invention provides a method for dynamically arranging battery storage locations, which reduces the overall energy consumption of the formation apparatus, thereby enhancing its energy efficiency.

The present invention proposes a method for dynamically arranging battery storage locations, applicable to a formation apparatus having a plurality of storage locations. Each storage location is defined in either a first battery group or a second battery group, and each storage location is configured to accommodate a battery with a test recipe. The method comprises the following steps: calculating, based on the test recipes of all batteries in the first battery group and the test recipes of all batteries in the second battery group, a first charge-discharge value associated with the first battery group and a second charge-discharge value associated with the second battery group within a target time interval; calculating, based on an additional test recipe of an additional battery, an additional charge-discharge value associated with the additional battery within the target time interval; calculating a first sum value of the first charge-discharge value and the additional charge-discharge value, and a second sum value of the second charge-discharge value and the additional charge-discharge value, respectively; comparing the first sum value and the second sum value to obtain a comparison result; and determining, based on the comparison result, whether the additional battery is to be arranged in a storage location of the first battery group or a storage location of the second battery group.

In some embodiments, a positive value of the first sum value or the second sum value may indicate that the corresponding first battery group or second battery group needs to draw power from an external power source, while a negative value of the first sum value or the second sum value may indicate that the corresponding first battery group or second battery group needs to discharge power to the external power source.

In some embodiments, the step of comparing the first sum value and the second sum value to obtain the comparison result may further comprise: determining whether the first sum value or the second sum value is closest to zero to obtain the comparison result, wherein the comparison result indicates that the additional battery is to be arranged in a storage location of the first battery group or the second battery group corresponding to the first sum value or the second sum value that is closest to zero. Additionally, the step of comparing the first sum value and the second sum value to obtain the comparison result may also comprise: determining whether the first charge-discharge value and the second charge-discharge value have the same sign as the additional charge-discharge value, respectively; and when both the first charge-discharge value and the second charge-discharge value have the same sign as the additional charge-discharge value, the comparison result indicates that the additional battery is to be arranged in a storage location of the first battery group or the second battery group corresponding to the smaller of the first sum value and the second sum value.

Furthermore, when the first charge-discharge value has an opposite sign to the additional charge-discharge value, and the second charge-discharge value does not have an opposite sign to the additional charge-discharge value, the comparison result indicates that the additional battery is to be arranged in a storage location of the first battery group.

In some embodiments, after the step of determining whether the first sum value and the second sum value are positive or negative, the method further comprises: when one of the first sum value and the second sum value is negative, and the absolute values of both the first sum value and the second sum value are less than a first threshold value, the comparison result indicates that the additional battery is to be arranged in a storage location of the first battery group or the second battery group corresponding to the negative value of the first sum value or the second sum value.

The present invention also proposes a method for dynamically arranging battery storage locations, applicable to a formation apparatus used for testing a plurality of batteries, wherein each battery corresponds to a test recipe, and the batteries are at least divided into a first battery group and a second battery group. The method comprises: calculating, based on the test recipes of all batteries in the first battery group and the test recipes of all batteries in the second battery group, a first charge-discharge value of the first battery group and a second charge-discharge value of the second battery group within a target time interval; calculating, based on an additional test recipe of an additional battery within the target time interval, an additional charge-discharge value; determining whether the first charge-discharge value and the second charge-discharge value have the same sign as the additional charge-discharge value, respectively, to obtain a comparison result; and determining, based on the comparison result, whether the additional battery is to be arranged in a storage location of the first battery group or the second battery group.

In some embodiments, the step of determining whether the first charge-discharge value and the second charge-discharge value have the same sign as the additional charge-discharge value to obtain the comparison result further comprises: when the first charge-discharge value has an opposite sign to the additional charge-discharge value, and the second charge-discharge value does not have an opposite sign to the additional charge-discharge value, the comparison result indicates that the additional battery is to be arranged in a storage location of the first battery group. When both the first charge-discharge value and the second charge-discharge value have the same sign as the additional charge-discharge value, the method further comprises calculating a first sum value of the first charge-discharge value and the additional charge-discharge value, and a second sum value of the second charge-discharge value and the additional charge-discharge value, respectively, wherein the comparison result indicates that the additional battery is to be arranged in a storage location of the first battery group or the second battery group corresponding to the smaller of the first sum value and the second sum value.

In summary, the method for dynamically arranging battery storage locations provided by the present invention first estimates the charge-discharge states of all batteries in the existing battery groups and the charge-discharge state of an additional battery, then selects the battery group with the least energy loss for the additional battery to join. As a result, the method for dynamically arranging battery storage locations provided by the present invention enables the formation apparatus to operate more energy-efficiently.

### BRIEF DESCRIPTION OF THE APPTERMINALED DRAWINGS

FIG. 1 is a functional block diagram illustrating a formation apparatus applying a method for dynamically arranging battery storage locations according to an embodiment of the present invention.

FIG. 2A is a schematic diagram illustrating the test recipes of all batteries in the first battery group according to an embodiment of the present invention.

FIG. 2B is a schematic diagram illustrating the test recipes of all batteries in the second battery group according to an embodiment of the present invention.

FIG. 3 is a functional block diagram illustrating a formation apparatus applying a method for dynamically arranging battery storage locations according to another embodiment of the present invention.

FIG. 4 is a flowchart illustrating the steps of a method for dynamically arranging battery storage locations according to an embodiment of the present invention.

FIG. 5 is a flowchart illustrating the steps of a method for dynamically arranging battery storage locations according to another embodiment of the present invention.

### DETAILED DESCRIPTION OF THE INVENTION

The features, targetions, and functions of the present invention are further disclosed below. However, it is only a few of the possible embodiments of the present invention, and the scope of the present invention is not limited thereto; that is, the equivalent changes and modifications done in accordance with the claims of the present invention will remain the subject of the present invention. Without departing from the spirit and scope of the invention, it should be considered as further enablement of the invention.

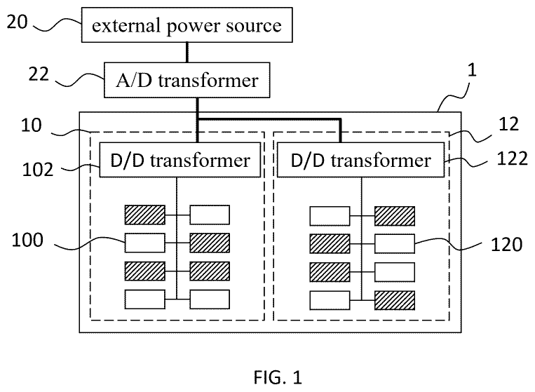

Referring to FIG. 1, FIG. 1 is a functional block diagram illustrating a formation apparatus applying a method for dynamically arranging battery storage locations according to an embodiment of the present invention. As shown in FIG. 1, the formation apparatus 1 comprises multiple storage locations, which can be categorized into storage locations 100 and storage locations 120. The storage locations 100 belong to the first battery group 10, while the storage locations 120 belong to the second battery group 12. In practice, the first battery group 10 can obtain the power required for the multiple storage locations 100 through a D/D transformer 102 (DC-to-DC transformer) and can also output power from the first battery group 10 via the D/D transformer 102. Although FIG. 1 depicts connections between the multiple storage locations 100, in reality, the power transmission between the storage locations 100 occurs through the D/D transformer 102 to ensure that each storage location 100 receives the correct voltage and current. Additionally, the formation apparatus 1 is electrically connected to an external power source 20. Since the external power source 20 may, for example, provide AC power (e.g., mains electricity), while the formation apparatus 1 operates on DC power, an A/D transformer 22 (AC-to-DC transformer) is required between the formation apparatus 1 and the external power source 20. In other words, the A/D transformer 22 can draw AC power from the external power source 20 and convert it into DC power for the formation apparatus 1, or the DC power from the formation apparatus 1 can be converted into AC power via the A/D transformer 22 and fed back to the external power source 20.

In one example, suppose a battery is placed in a storage location 100 and requires charging at 100 watts. If both the D/D transformer 102 and the A/D transformer 22 each incur a 10% energy loss, it can be calculated that approximately 111.1 watts need to be supplied to the D/D transformer 102 for the storage location 100 to receive 100 watts of power. Further calculation shows that approximately 123.5 watts need to be supplied to the A/D transformer 22 for the D/D transformer 102 to receive 111.1 watts. Assuming negligible losses between the external power source 20 and the A/D transformer 22, the external power source 20 must provide 123.5 watts for the storage location 100 to receive 100 watts, resulting in an additional loss of 23.5 watts. To address this issue, aside from reducing the energy loss ratios of the D/D transformer 102 and the A/D transformer 22, this embodiment optimizes energy use by enabling power to be utilized as much as possible among the storage locations within the same battery group. Although there is still some energy loss when power is transmitted between storage locations within the same battery group via the D/D transformer 102, bypassing the A/D transformer 22 eliminates the additional loss from that stage, thus preventing energy waste.)

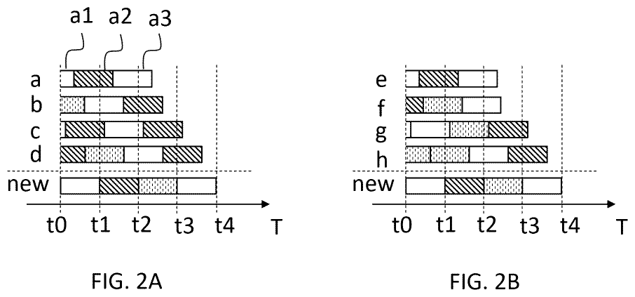

For a practical example, please refer to both FIG. 1 and FIG. 2A. FIG. 2A is a schematic diagram illustrating the test recipes of all batteries in the first battery group 10 according to an embodiment of the present invention. As shown, assume the first battery group 10 has eight storage locations 100. In FIG. 1, four of these storage locations 100 are shaded with diagonal lines, indicating that these storage locations 100 are already occupied by batteries. Here, it is assumed that these four storage locations 100 contain batteries a, b, c, and d, respectively. Taking battery a as an example to explain the test recipe, FIG. 2A shows that at time t0, battery a is executing task a1 from its test recipe, followed by tasks a2 and a3. Assuming no anomalies occur with battery a, it will be removed from the formation apparatus 1 after completing task a3 (i.e., when the test recipe is fully executed). Since a test recipe comprises various types of charging tasks, this embodiment simplifies the demonstration by using only charging tasks (shaded with diagonal lines in FIG. 2A), resting tasks (shaded with dotted lines in FIG. 2A), and discharging tasks (blank in FIG. 2A). Specifically, a charging task refers to any task where battery a needs to receive power from the D/D transformer 102, including various charging types such as constant voltage or constant current. A resting task refers to any task where battery a neither receives power from nor releases power to the D/D transformer 102. A discharging task refers to any task where battery a releases power to the D/D transformer 102. Naturally, this embodiment does not limit the types of tasks in a test recipe, and those skilled in the art can design more complex task details as needed.

It is worth noting that this embodiment does not require batteries within the same battery group to have identical or different test recipes. For example, batteries a and b may have different test recipes, while batteries b and c may have the same test recipe. Additionally, since batteries a, b, c, and d may not be placed into the storage locations 100 at the same time, at a given time point (or within a time interval), they are unlikely to be uniformly charging or discharging. Instead, some batteries may be charging, some discharging, or some batteries may be resting without charging or discharging.

As illustrated in FIG. 1, when the first battery group 10 has four vacant storage locations 100 and the second battery group 12 also has four vacant storage locations 120, this embodiment demonstrates how an operator can quickly determine whether a new battery (referred to as “new”) should be placed in the first battery group 10 or the second battery group 12. For instance, if a new battery “new” is to be added at time t0, it comes with a corresponding additional test recipe. Suppose the additional test recipe indicates that from time t0 to t1, the new battery “new” performs a discharging task; from t1 to t2, it performs a charging task; from t2 to t3, it performs a resting task; and from t3 to t4, it performs a discharging task. This embodiment determines whether the new battery “new” should be placed in a storage location 100 of the first battery group 10 or a storage location 120 of the second battery group 12 based on the test recipes of all batteries in the storage locations.

In detail, the method for dynamically arranging battery storage locations of the present invention first determines the test recipes of all batteries in the storage locations 100 of the first battery group 10. A target time interval is selected as a reference to estimate the charge-discharge value (first charge-discharge value) of all batteries within this interval. In one example, assuming the target time interval is from t0 to t1, this embodiment calculates the charge-discharge values of batteries a, b, c, and d during this period. For instance, since batteries a and c perform both discharging and charging tasks for parts of the time between t0 and t1, this embodiment can calculate the power required or released by each task during t0 to t1 and compute the subtotal charge-discharge values for batteries a, b, and c over this interval.

Similarly, battery b performs a discharging task for part of the time between t0 and t1, while battery d performs a charging task for part of the time. Both batteries b and d also have periods of resting tasks (no power consumption). This embodiment can likewise compute the subtotal charge-discharge values for batteries b and d between t0 and t1. For simplicity, assume the charge-discharge values of batteries a, b, c, and d are +5, −10, +15, and +10 units of energy, respectively. The total charge-discharge value (first charge-discharge value) for the first battery group 10 is then +20 units of energy. Additionally, between t0 and t1, the additional test recipe of the new battery “new” indicates it only performs a discharging task, with an estimated charge-discharge value (additional charge-discharge value) of −20 units of energy. Thus, adding the first charge-discharge value and the additional charge-discharge value yields a total estimated charge-discharge value of 0 units of energy (first sum value) if the new battery “new” is added to a storage location 100 in the first battery group 10 during t0 to t1.

Likewise, the method for dynamically arranging battery storage locations of the present invention also determines the test recipes of all batteries in the storage locations 120 of the second battery group 12. For example, FIG. 2B is a schematic diagram illustrating the test recipes of all batteries in the second battery group 12 according to an embodiment of the present invention. Here, this embodiment similarly estimates the charge-discharge value (second charge-discharge value) of all batteries in the second battery group 12 during the time interval from t0 to t1. In one example, this embodiment calculates the charge-discharge values of batteries e, f, g, and h in the second battery group 12 during t0 to t1. For simplicity, assume the charge-discharge values of batteries e, f, g, and h are +5, +10, −20, and 0 units of energy, respectively. The total charge-discharge value (second charge-discharge value) for the second battery group 12 is then −5 units of energy. Additionally, between t0 and t1, the additional charge-discharge value of the new battery “new” is known to be −20 units of energy. Thus, adding the second charge-discharge value and the additional charge-discharge value yields a total estimated charge-discharge value of −25 units of energy (second sum value) if the new battery “new” is added to a storage location 120 in the second battery group 12 during t0 to t1.

From the above, if the calculated sum value for a battery group is positive, it indicates that the battery group needs to draw power from the external power source 20. If the sum value is negative, it indicates that the battery group needs to discharge power to the external power source 20. If the sum value is exactly zero, it indicates that the battery group neither needs to draw power from nor discharge power to the external power source 20, achieving a balanced state.

After obtaining the first sum value and the second sum value, the method for dynamically arranging battery storage locations of the present invention compares the magnitudes of the first sum value and the second sum value. In one example, the method may select the option with the least energy loss, such as determining that the first sum value (+0) is closer to zero than the second sum value (−25), thus choosing to place the new battery “new” in a storage location 100 of the first battery group 10. The rationale is that if the new battery “new” is added to the first battery group 10, the group achieves a balanced state, eliminating the need for power transmission through the A/D transformer 22 and thereby avoiding losses at that stage.

In another example, suppose the calculated first sum value is +10 and the second sum value is −10. The method for dynamically arranging battery storage locations of the present invention may opt to avoid drawing power from the external power source 20. For instance, it may determine that the first sum value (+10) requires drawing power from the external power source 20, while the second sum value (−10) involves discharging power to the external power source 20. However, drawing power from the external power source 20 incurs electricity costs. To save on electricity costs, the method may choose to place the new battery “new” in a storage location of the battery group with a negative sum value. However, if the absolute values of the first sum value and the second sum value differ significantly—e.g., the first sum value is +10 (absolute value 10) and the second sum value is −100 (absolute value 100)—and this difference exceeds a preset threshold, the method may instead select the option with the smaller absolute sum value, such as placing the new battery “new” in a storage location 100 of the first battery group 10, where the absolute value of the first sum value is 10.

In addition to using sum values to determine which battery group's storage location the new battery should join, the method for dynamically arranging battery storage locations of the present invention can also use whether the first charge-discharge value, the second charge-discharge value, and the additional charge-discharge value have the same sign as a basis for judgment. For example, suppose the first charge-discharge value, the second charge-discharge value, and the additional charge-discharge value are all positive (same sign), meaning both the first battery group 10 and the second battery group 12 need to draw power from the external power source 20. Since the additional charge-discharge value is positive, adding the new battery to either the first battery group 10 or the second battery group 12 will increase the power drawn from the external power source 20. In this case, the method selects the smaller of the first charge-discharge value and the second charge-discharge value. Assume the first charge-discharge value is +10, the second charge-discharge value is +50, and the additional charge-discharge value is +10. Adding the second charge-discharge value and the additional charge-discharge value results in +60, while adding the first charge-discharge value and the additional charge-discharge value results in only +20. Since drawing power from the external power source 20 is unavoidable, and assuming a 10% loss in the A/D transformer 22, the energy loss is 2 units if the new battery is added to the first battery group 10, compared to 6 units if added to the second battery group 12. Clearly, adding the new battery to a storage location in the first battery group 10 is more energy-efficient. Thus, in this example, the method selects the smaller of the first charge-discharge value and the second charge-discharge value.

Similarly, suppose the first charge-discharge value, the second charge-discharge value, and the additional charge-discharge value are all negative (same sign), meaning both the first battery group 10 and the second battery group 12 need to discharge power to the external power source 20. Since the additional charge-discharge value is negative, adding the new battery to either the first battery group 10 or the second battery group 12 will increase the power discharged to the external power source 20. In this case, the method still selects the smaller of the first charge-discharge value and the second charge-discharge value. For the same reasons as the previous example, as long as the first charge-discharge value, the second charge-discharge value, and the additional charge-discharge value have the same sign, choosing the smaller value reduces energy loss due to the A/D transformer 22, thus enhancing energy efficiency.

Following the above, if only one of the first charge-discharge value and the second charge-discharge value has the same sign as the additional charge-discharge value, while the other has an opposite sign, the method for dynamically arranging battery storage locations of the present invention selects the battery group with the opposite sign for the new battery. For example, assume the first charge-discharge value is +30, the second charge-discharge value is −30, and the additional charge-discharge value is −10. The first charge-discharge value and the additional charge-discharge value have opposite signs (opposite polarity), while the second charge-discharge value and the additional charge-discharge value have the same sign (same polarity). In this case, the method chooses to place the new battery in a storage location of the first battery group 10. The rationale is that the first charge-discharge value and the additional charge-discharge value can offset each other, making the first sum value (first charge-discharge value plus additional charge-discharge value) closer to zero than the original first charge-discharge value, thus facilitating a balanced charge-discharge state.

The foregoing describes two judgment approaches to determine whether the new battery should join a storage location in the first battery group or the second battery group: one based on comparing the first sum value and the second sum value, and the other based on whether the first charge-discharge value, the second charge-discharge value, and the additional charge-discharge value have the same sign. This embodiment does not limit the approach. Those skilled in the art can see from the examples that different conditions may be set based on different objectives, such as reducing electricity costs or minimizing energy loss. Additionally, it is possible to first assess whether the first charge-discharge value, the second charge-discharge value, and the additional charge-discharge value have the same sign, then incorporate a comparison of the first sum value and the second sum value, enabling a more flexible dynamic evaluation approach.

It is worth noting that the target time interval in the foregoing embodiment is chosen as t0 to t1, corresponding to the time interval of the first task in the additional test recipe, but this embodiment is not limited to this choice. As shown in FIG. 2, between t2 and t3, batteries a and b are expected to complete their test recipes and leave the formation apparatus 1. Between t3 and t4, batteries c and d are also expected to complete their test recipes and leave the formation apparatus 1. Given that existing batteries will gradually complete their test recipes and exit the formation apparatus 1, and considering potential unexpected anomalies during the process, selecting an overly long target time interval may not be appropriate. In other words, choosing a shorter target time interval ensures relative stability in the battery set, thereby improving estimation accuracy. In one example, when it is time to add the next battery, that battery can be treated as the new battery, and the aforementioned calculation and judgment methods can be applied to determine the appropriate storage location. Of course, if multiple new batteries are scheduled to be sequentially placed into the formation apparatus 1, their test recipes can also be preemptively incorporated into the sum value calculations.

Those skilled in the art will understand that, for illustrative purposes, the foregoing embodiment describes the spirit of the present invention with simplified concepts. In practice, factors such as the diversity of test recipes, the number of battery groups, the number of storage locations in each battery group, and the length of the target time interval increase the complexity of calculations and judgments. For example, dynamic programming, multidimensional matrices, or multivariable equations may be required to derive optimal solutions. The present invention does not limit the computational methods. In special cases, if only one storage location remains vacant in both the first and second battery groups, the new battery can be directly placed in that sole vacant location without further judgment, as there are no alternatives to choose from. From the above, it is clear that the present invention is applicable when the formation apparatus has two or more vacant storage locations available for selection, leveraging battery pairing within the same battery group to reduce the need for charging or discharging to the grid (e.g., external power source).

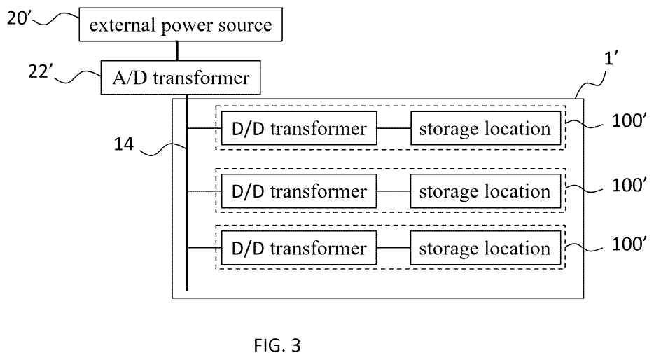

In another example, please refer to FIG. 3, which is a functional block diagram illustrating a formation apparatus applying a method for dynamically arranging battery storage locations according to another embodiment of the present invention. Similar to FIG. 1, the formation apparatus 1′ in FIG. 3 also contains multiple storage locations, each within different storage location units 100′. Additionally, the formation apparatus 1′ is electrically connected to an external power source 20′ via an A/D transformer 22′ (AC-to-DC transformer). Unlike FIG. 1, the formation apparatus 1′ comprises multiple D/D transformers, with each storage location unit 100′ containing at least one D/D transformer and one storage location. As shown in FIG. 3, using several storage location units 100′ as examples, these units are electrically connected via a power line 14, with each unit serially connecting a D/D transformer and a storage location. In practice, the storage locations described in FIG. 3 are generally equivalent to those in FIG. 1, with the primary difference being the number and placement of D/D transformers. In the example depicted in FIG. 3, power still primarily circulates internally between the power line 14 and the storage location units 100′, reducing the flow of power to or from the external power source 20′ via the A/D transformer 22′. The application example in FIG. 3 is largely similar to that in FIG. 1, and this embodiment will not elaborate further here.

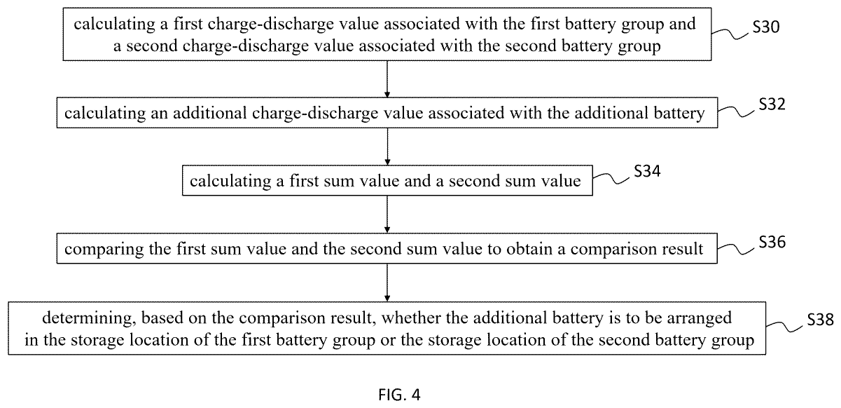

To illustrate the method for dynamically arranging battery storage locations of the present invention, please refer to FIGS. 1 to 3 together. FIG. 4 is a flowchart illustrating the steps of a method for dynamically arranging battery storage locations according to an embodiment of the present invention. As shown, in step S30, calculate, based on the test recipes of all batteries in the first battery group 10 and the test recipes of all batteries in the second battery group 12, a first charge-discharge value associated with the first battery group and a second charge-discharge value associated with the second battery group within a target time interval (e.g., t0 to t1 as described earlier). In step S32, calculate, based on the additional test recipe of a new battery, an additional charge-discharge value associated with the new battery within the target time interval. In step S34, calculate a first sum value of the first charge-discharge value and the additional charge-discharge value, and a second sum value of the second charge-discharge value and the additional charge-discharge value, respectively. In step S36, compare the first sum value and the second sum value to obtain a comparison result. In step S38, determine, based on the comparison result, whether the new battery is to be arranged in a storage location of the first battery group or the second battery group. These steps have been described in detail in the foregoing embodiments and will not be repeated here.

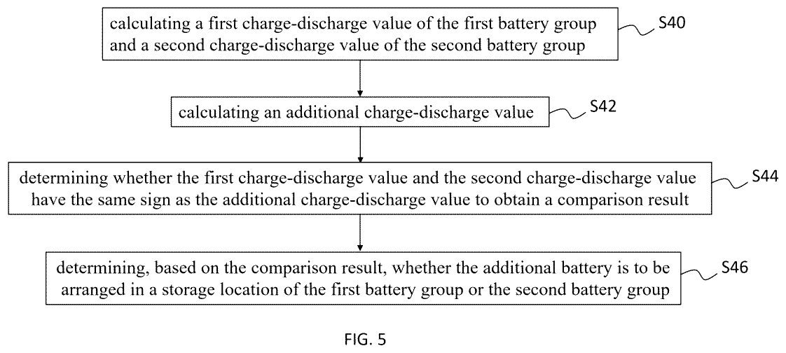

Please refer to FIGS. 1 to 4 together. FIG. 5 is a flowchart illustrating the steps of a method for dynamically arranging battery storage locations according to another embodiment of the present invention. As shown, in step S40, calculate, based on the test recipes of all batteries in the first battery group and the test recipes of all batteries in the second battery group, a first charge-discharge value of the first battery group and a second charge-discharge value of the second battery group within a target time interval. In step S42, calculate, based on the additional test recipe of a new battery, an additional charge-discharge value associated with the new battery within the target time interval. In step S44, determine whether the first charge-discharge value and the second charge-discharge value have the same sign as the additional charge-discharge value, respectively, to obtain a comparison result. In step S46, determine, based on the comparison result, whether the new battery is to be arranged in a storage location of the first battery group or the second battery group. These steps have also been described in detail in the foregoing embodiments and will not be repeated here.

In summary, the method for dynamically arranging battery storage locations provided by the present invention first estimates the charge-discharge states of all batteries in the existing battery groups and the charge-discharge state of a new battery, then selects the battery group with the least energy loss for the new battery to join. As a result, the method for dynamically arranging battery storage locations provided by the present invention enables the formation apparatus to operate more energy-efficiently.

What is claimed is:

1. A method for dynamically arranging battery storage location, applicable to a formation apparatus having a plurality of storage locations, each storage location is defined in either a first battery group or a second battery group, and each storage location is configured to accommodate a battery with a test recipe, the method comprising:
calculating, based on the test recipes of all batteries in the first battery group and the test recipes of all batteries in the second battery group, a first charge-discharge value associated with the first battery group and a second charge-discharge value associated with the second battery group within a target time interval;
calculating, based on an additional test recipe of an additional battery, an additional charge-discharge value associated with the additional battery within the target time interval;
calculating a first sum value of the first charge-discharge value and the additional charge-discharge value, and a second sum value of the second charge-discharge value and the additional charge-discharge value, respectively;
comparing the first sum value and the second sum value to obtain a comparison result; and
determining, based on the comparison result, whether the additional battery is to be arranged in the storage location of the first battery group or the storage location of the second battery group.

2. The method for dynamically arranging battery storage location according to claim 1, wherein a positive value of the first sum value or the second sum value indicates that the corresponding first battery group or the corresponding second battery group needs to draw power from an external power source, and a negative value of the first sum value or the second sum value indicates that the corresponding first battery group or the corresponding second battery group needs to discharge power to the external power source.

3. The method for dynamically arranging battery storage location according to claim 2, wherein the step of comparing the first sum value and the second sum value to obtain the comparison result comprises:
determining whether the first sum value or the second sum value is closest to zero to obtain the comparison result;
wherein the comparison result indicates that the additional battery is to be arranged in the storage location of the first battery group or the storage location of the second battery group corresponding to the first sum value or the second sum value that is closest to zero.

4. The method for dynamically arranging battery storage location according to claim 2, wherein the step of comparing the first sum value and the second sum value to obtain the comparison result comprises:
determining whether the first charge-discharge value and the second charge-discharge value have the same sign as the additional charge-discharge value, respectively; and
when both the first charge-discharge value and the second charge-discharge value have the same sign as the additional charge-discharge value, the comparison result indicates that the additional battery is to be arranged in a storage location of the first battery group or the second battery group corresponding to the smaller of the first sum value and the second sum value.

5. The method for dynamically arranging battery storage location according to claim 4, further comprising:
when the first charge-discharge value has an opposite sign to the additional charge-discharge value, and the second charge-discharge value does not have an opposite sign to the additional charge-discharge value, the comparison result indicates that the additional battery is to be arranged in a storage location of the first battery group.

6. The method for dynamically arranging battery storage location according to claim 2, further comprising:
when one of the first sum value and the second sum value is negative, and absolute values of both the first sum value and the second sum value are less than a first threshold value, the comparison result indicates that the additional battery is to be arranged in a storage location of the first battery group or the second battery group corresponding to the negative value of the first sum value or the second sum value.

7. A method for dynamically arranging battery storage location, applicable to a formation apparatus used for testing a plurality of batteries, each battery corresponds to a test recipe, and the batteries are at least divided into a first battery group and a second battery group, the method comprising:
calculating, based on the test recipes of all batteries in the first battery group and the test recipes of all batteries in the second battery group, a first charge-discharge value of the first battery group and a second charge-discharge value of the second battery group within a target time interval;
calculating, based on an additional test recipe of an additional battery within the target time interval, an additional charge-discharge value;
determining whether the first charge-discharge value and the second charge-discharge value have the same sign as the additional charge-discharge value, respectively, to obtain a comparison result; and
determining, based on the comparison result, whether the additional battery is to be arranged in a storage location of the first battery group or the second battery group.

8. The method for dynamically arranging battery storage location according to claim 7, wherein the step of determining whether the first charge-discharge value and the second charge-discharge value have the same sign as the additional charge-discharge value to obtain the comparison result further comprises:
when the first charge-discharge value has an opposite sign to the additional charge-discharge value, and the second charge-discharge value does not have an opposite sign to the additional charge-discharge value, the comparison result indicates that the additional battery is to be arranged in a storage location of the first battery group.

9. The method for dynamically arranging battery storage location according to claim 8, further comprising:
when both the first charge-discharge value and the second charge-discharge value have the same sign as the additional charge-discharge value, calculating a first sum value of the first charge-discharge value and the additional charge-discharge value, and a second sum value of the second charge-discharge value and the additional charge-discharge value, respectively; and
the comparison result indicates that the additional battery is to be arranged in a storage location of the first battery group or the second battery group corresponding to the smaller of the first sum value and the second sum value.
